(19) United States
(12) Patent Application Publication
(10) Pub. No.: US 2015/0168086 A1
(43) Pub. Date: Jun. 18, 2015

(54) Carbon Fiber Heat Exchangers

(71) Applicant: KULR Technology Corporation, Santa Clara, CA (US)

(72) Inventors: Timothy Ray Knowles, San Diego, CA (US); Michael Gerald Carpenter, San Diego, CA (US); Yoshio Robert Yamaki, San Diego, CA (US)

(21) Appl. No.: 14/572,761

(22) Filed: Dec. 16, 2014

Related U.S. Application Data
(60) Provisional application No. 61/916,743, filed on Dec. 16, 2013.

(51) Int. Cl. F28F 21/02; H05K 7/20

(52) U.S. Cl. CPC F28F 21/02; H05K 7/20163; H05K 7/20254

(57) ABSTRACT

A heat sink comprises a base for receiving heat, a cover having at least one exhaust channel, and carbon fibers. The carbon fibers are disposed between the base and the cover in a predefined pattern. The patterned carbon fibers form at least one inlet channel, where the at least one inlet channel allows for receiving a coolant into the patterned carbon fibers. The at least one exhaust channel allows for expelling of the coolant from the patterned carbon fibers.

### CROSS REFERENCE

This application claims priority from a provisional patent application entitled “Carbon Fiber Heat Exchangers” filed on Dec. 16, 2013 and having an Application No. 61/916,743. Said application is incorporated herein by reference.

### FIELD OF INVENTION

The invention relates to heat sinks and, in particular, to heat sinks that have patterned carbon fiber velvet heat exchangers.

### BACKGROUND

Electronic microprocessors and other heat-generating electronic components concentrate thermal energy in a very small space which requires thermal cooling to maintain acceptable operating conditions. Over the years, numerous solutions addressing this heating issue have been implemented for a variety of applications. For example, thermally conductive pistons, micro-bellows, water-cooled cold plates, heat sink with fins, heat pipes, fans and the like have been used to attempt to solve the heating problem associated with these complex, highly integrated electronic circuitry.

Computer heat sinks are generally among the largest and heaviest components of an electronic unit because they are made of conductive metals such as aluminum or copper. In order to reduce costs and decrease weight and bulkiness, there exists a need for new heat sinks that have low overall thermal resistance, a small size, and light weight construction.

### SUMMARY OF INVENTION

Briefly, the present invention discloses a heat sink comprising: a base for receiving heat; a cover having at least one exhaust channel; and carbon fibers, wherein the carbon fibers are disposed between the base and the cover in a predefined pattern and wherein the patterned carbon fibers form at least one inlet channel, wherein the at least one inlet channel allows for receiving a coolant into the patterned carbon fibers, and wherein the at least one exhaust channel allows for expelling of the coolant from the patterned carbon fibers.

### DESCRIPTION OF THE DRAWINGS

The foregoing and other objects, aspects, and advantages of the invention can be better understood from the following detailed description of the preferred embodiment of the invention when taken in conjunction with the accompanying drawings in which:

FIG. 1 illustrates a top view of an uncovered heat sink having patterned carbon fibers disposed on a base of the heat sink.

FIG. 2 illustrates a top view of a heat sink having patterned carbon fibers disposed on the base of the heat sink.

FIG. 3 illustrates a side view of a heat sink having patterned carbon fibers disposed on the base of the heat sink, forming inlet channels.

FIG. 4 illustrates a side view of a heat sink having patterned carbon fibers connected to a heat source and a coolant pump.

### DETAILED DESCRIPTION OF THE PREFERRED EMBODIMENTS

A figure of merit for heat exchanger materials is the ratio of conductivity to density. Commercial pitch carbon fiber is approximately an order of magnitude better than metals on this basis. Also useful is that carbon fiber has a suitably small diameter (˜10 micrometers) that provides a large surface area per volume without further processing, whereas metals need skiving or extrusion steps to create the surface area. Thus, in the present disclosure, carbon fibers (also referred to as fibers or carbon fiver velvet) are used as pin-fins for heat transfer between a solid base of a heat sink and some coolant, whether that coolant be liquid or gaseous. Carbon fibers provide conduction of heat from the heated base to the passing coolant. The number of fibers is selected based on the desired heat transfer rate, with more fibers providing more conduction. However, the fibers present high flow resistance to the coolant. The resistance is proportional to the thickness of the velvet in the flow direction over the cross-sectional flow area.

To promote heat transfer with modest pressure drop, the carbon fibers can be arranged vertically as a meandering fence separating inlet and exit channels where the pressure drop of the coolant is low. The main pressure drop occurs as the air passes through the fiber fence where the heat is acquired. Such means of reducing flow resistance while maintaining heat transfer is critical in practical applications.

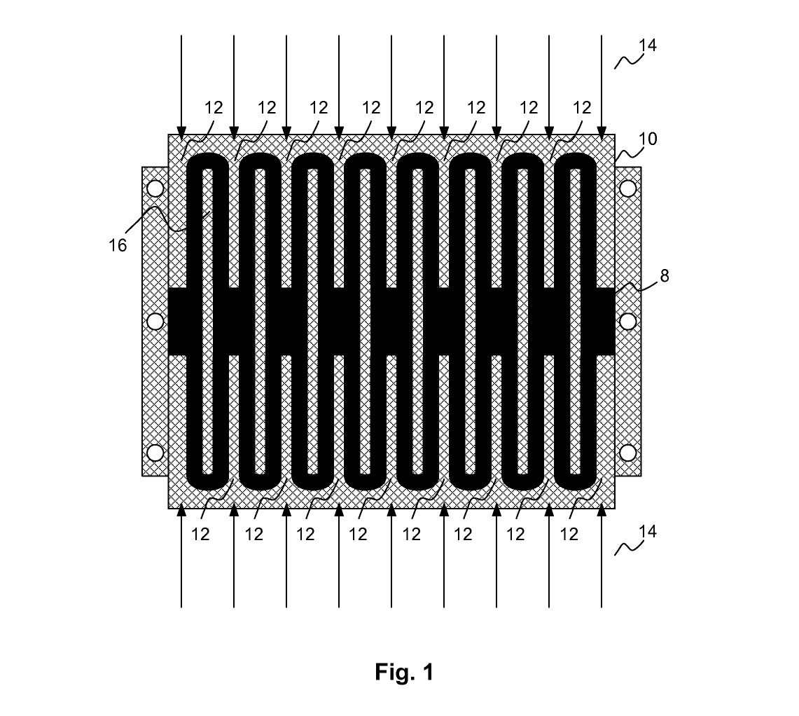

FIG. 1 illustrates a top view of an uncovered heat sink having patterned carbon fibers disposed on a base of the heat sink. An uncovered heat sink comprises carbon fibers 8 (also referred to as carbon fiber velvet) and a base 10. The carbon fibers 8 are bonded to the base 10. The carbon fibers 8 can be electroflocked into a velvet configuration with the carbon fibers 8 substantially standing perpendicular to the base 10 in a layer of thermally conductive adhesive or other bonding agent. The base 10 is a conductive substrate, where the carbon fibers 8 are thermodynamically bonded to the base 10. The base 10 can be further contacted with a heat source (not shown).

The carbon fibers 8 serve as small diameter pin fins, conducting heat from the base 10. The length of the carbon fibers 8 and the number of carbon fibers 8 per area can be optimized for a particular application depending on the constraints for that application in terms of performance, volume, mass, and coolant pumping power.

In general, electroflocking is useful for fiber lengths from 0.1 to 10 millimeters, with the number packing density typically reaching hundreds of carbon fibers per square millimeter, so that a wide range of surface area is achievable. However, it is understood that other carbon fiber bonding methods can be used in conjunction with the present disclosure. The small diameter of the carbon fibers can be conducive to small thermal boundary layers so that convective heat transfer on the fibers is large compared to that on planar fins of conventional metal heat exchangers.

The carbon fibers 8 are disposed in a predefined pattern, forming inlet channels 12 to allow for coolant (e.g., gas, liquid, or other material) from outside of the heat sink to flow into the patterned carbon fibers 8. The patterned carbon fibers 8 form a semipermeable fence that allows the coolant to flow through the inlet channels 12 and through the fence as well. Thus, the inlet channels 12 allow the coolant to travel into the patterned carbon fibers 8 without having to drive the coolant into the carbon fibers 8 at high pressure. An inlet coolant flow 14 shows that the coolant can enter the heat sink via the inlet channels 12.

To control pressure drop in the carbon fiber velvet heat exchanger of the heat sink, the carbon fibers 8 are patterned so that there are alternating inlet and outlet channels with a thin fence of carbon velvet. The channels interpenetrate and the fence meanders back and forth in the present disclosure. This configuration allows coolant to flow easily through the channels on the inlet side of the thin fence, then permeate through the fence absorbing heat from the carbon fibers 8, and then flow easily through the exhaust channels (not shown).

Typically, the heat sink will have a cover as well having at least one or more exhaust channels to allow for the heated coolant to be expelled from the heat sink. The following figures of the present disclosure will provide examples of such cover.

A person having ordinary skill in the art can understand that the predefined pattern of the carbon fibers 8 can be varied according to principles disclosed in the present disclosure. As long as the predefined pattern allow for at least one inlet channel and at least one outlet channel, then other obvious configurations can be implemented based on this disclosure by a person having ordinary skill in the art. Those other configurations are meant to be captured by the present disclosure as well. The carbon fiber pattern provided in FIG. 1 is an example of one of the many predefined patterns that the carbon fibers 8 can be arranged in for the sake of understanding the main principles of the present disclosure.

Furthermore, in certain embodiments, the patterned carbon fibers 8 may form at least one partitioned channels 16, where the coolant traverses from the at least one inlet channels 12, through the patterned carbon fibers 8, and then into the at least one partitioned channels. The coolant within the at least one partitioned channels 16 may further traverse back through the carbon fibers 8 or exit the patterned carbon fibers 8 via the at least one exhaust channel.

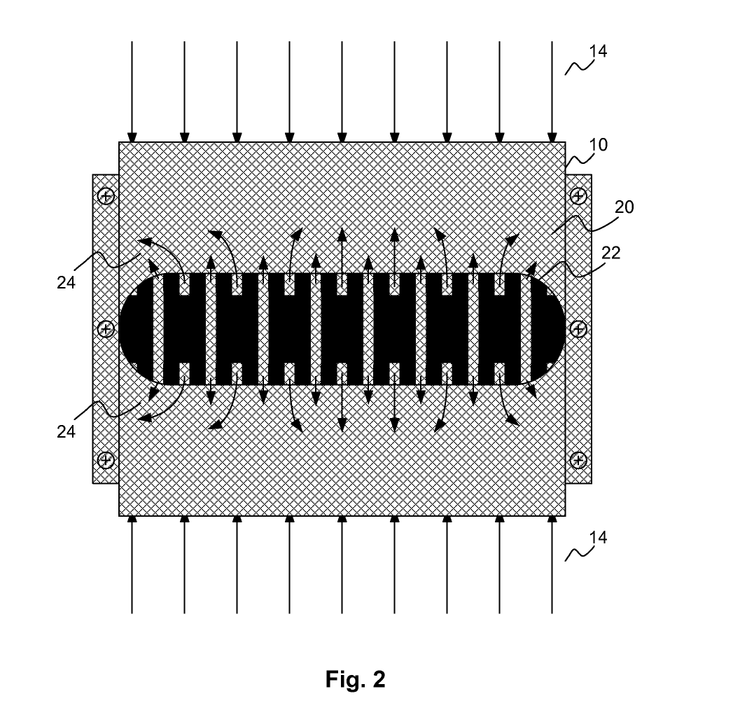

FIG. 2 illustrates a top view of a heat sink having patterned carbon fibers disposed on the base of the heat sink. The heat sink of the present disclosure can further comprise a cover 20 disposed on top of the carbon fibers 8. The cover 20 can have one or more openings 22 (also referred to as one or more exhaust channels), where the coolant flowing through the carbon fibers 8 can be expelled from the heat sink. The expelled coolant flow 24 can be substantially perpendicular to the inlet coolant flow 14.

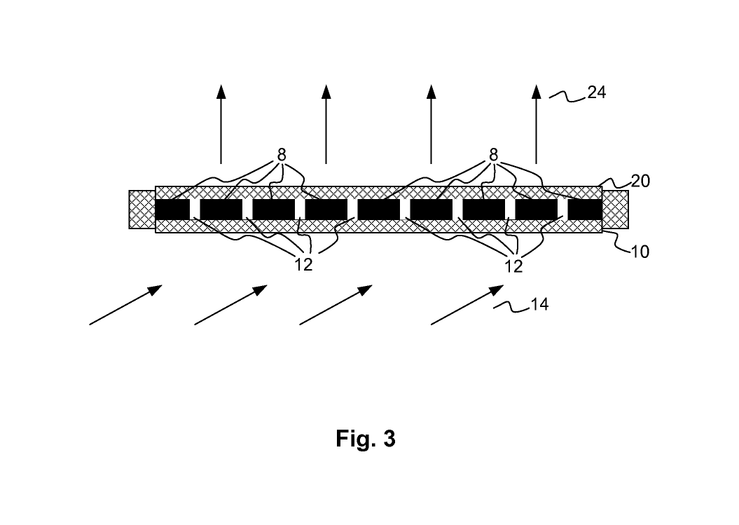

FIG. 3 illustrates a side view of a heat sink having patterned carbon fibers disposed on the base of the heat sink, forming inlet channels. In a side view of the heat sink, the base 10, the cover 20, inlet channels 12, carbon fibers 8 can be seen. The carbon fibers 8 are disposed between the cover 20 and the base 10. The coolant can travel along the inlet coolant flow 14 and through the carbon fibers 8 and the inlet channels 12. The coolant can be heated by the base 10 and from the carbon fibers 8. The heated coolant can be expelled from the heat sink, traveling in the direction of the exhaust coolant flow 24.

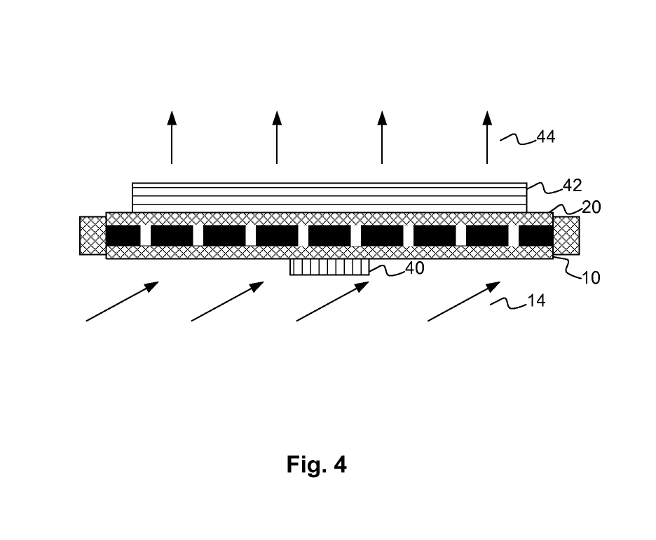

FIG. 4 illustrates a side view of a heat sink having patterned carbon fibers connected to a heat source and a coolant pump. The heat sink of the present disclosure can further have a heat source 40 connected to the base 10 and a coolant pump 42 connected to the cover 20. The cover 20 of the present disclosure can weigh less and be less costly than the base 10 since the cover can be made of polymer, a cheaper and lighter material than highly conductive metal alloys, e.g., aluminum, cooper, or other metals. Furthermore, the overall pressure drop through the heat sink can be set within the capability of the coolant pump (e.g., a centrifugal computer fan).

While the present invention has been described with reference to certain preferred embodiments or methods, it is to be understood that the present invention is not limited to such specific embodiments or methods. Rather, it is the inventor's contention that the invention be understood and construed in its broadest meaning as reflected by the following claims. Thus, these claims are to be understood as incorporating not only the preferred methods described herein but all those other and further alterations and modifications as would be apparent to those of ordinary skilled in the art.

We claim:

1. A heat sink comprising:
a base for receiving heat from a heat source;
a cover having at least one exhaust channel; and
carbon fibers, wherein the carbon fibers are disposed between the base and the cover in a predefined pattern and wherein the patterned carbon fibers form at least one inlet channel,
wherein the at least one inlet channel allows for receiving a coolant into the patterned carbon fibers, and
wherein the at least one exhaust channel allows for expelling of the coolant from the patterned carbon fibers.

2. The heat sink of claim 1 wherein the base is flat, wherein the carbon fibers are disposed substantially perpendicular to the base, and wherein coolant flow is substantially perpendicular to the carbon fibers.

3. The heat sink of claim 1 wherein the base is a conductive substrate, wherein the carbon fibers are thermodynamically bonded to the base, and wherein the conductive substrate contacts the heat source.

4. The heat sink of claim 1 further comprising a coolant pump, wherein the coolant pump is disposed on the cover to coolant pump the exhaust from the at least one exhaust channel.

5. The heat sink of claim 1 further comprising a suction blower, wherein the coolant is air, wherein the suction blower is disposed on the cover, and wherein the suction blower draws the air through the at least one inlet channels, then through the patterned carbon fiber, and finally through the at least one exhaust channels.

6. The heat sink of claim 1 wherein the coolant is a gas, wherein the gas enters the patterned carbon fibers via the at least one inlet channel, wherein the gas traverses the at least one inlet channel and between certain ones of the patterned carbon fibers, wherein, while the gas traverses, the gas receives heat from the carbon fibers and the base, and wherein the heated gas exits the patterned carbon fibers via the at least one exhaust channel.

7. The heat sink of claim 1 wherein the coolant is a liquid, wherein the liquid enters the patterned carbon fibers via the at least one inlet channel, wherein the liquid traverses the at least one inlet channel and between certain ones of the patterned carbon fibers, wherein, while the gas traverses, the gas receives heat from the carbon fibers and the base, and wherein the heated gas exits the patterned carbon fibers via the at least one exhaust channel.

8. The heat sink of claim 1 wherein the patterned carbon fibers form at least one partitioned channels, wherein the coolant traverses from the at least one inlet channels, through the patterned carbon fibers, and then into the at least one partitioned channels, wherein, while the coolant traverses, the coolant receives heat from the carbon fibers and the base, and wherein the heated coolant exits the patterned carbon fibers via the at least one exhaust channel.

9. The heat sink of claim 1 wherein density of the carbon fibers is determined as a function of one or more of the following: a type of the coolant; a type of the carbon fiber; a sizing of the carbon fiber; a sizing of the at least one inlet channel; and a sizing of the at least one outlet channel.
